(19) United States
(12) Patent Application Publication
(10) Pub. No.: US 2026/0032830 A1
(43) Pub. Date: Jan. 29, 2026

(54) CONTROL DEVICE

(71) Applicant: MITSUBA Corporation, Gunma (JP)

(72) Inventor: HIKARU SAWADA, Gunma (JP)

(73) Assignee: MITSUBA Corporation, Gunma (JP)

(21) Appl. No.: 19/260,616

(22) Filed: Jul. 7, 2025

(30) Foreign Application Priority Data
Jul. 23, 2024 (JP) 2024-117855

(51) Int. Cl. H05K 5/00

(52) U.S. Cl. CPC H05K 5/0047

(57) ABSTRACT

A control device includes a circuit board, a connector, a first case and a second case, and a liquid-tight adhesive. The first case and the second case are coupled to each other to accommodate the circuit board inside, and have a holding opening formed in a part of mutually abutting portions for holding the connector. The adhesive is filled between the holding opening and the outer peripheral surface of the connector. A case-side concave-convex engagement portion is provided annularly on the contact portion of the holding opening with the outer peripheral surface of the connector. A connector-side concave-convex engagement portion to be engaged with the case-side concave-convex engagement portion is provided annularly on the contact portion of the outer peripheral surface of the connector with the holding opening.

### CROSS-REFERENCE TO RELATED APPLICATION

This application claims the priority benefit of Japanese application serial no. 2024-117855, filed on Jul. 23, 2024. The entirety of the above-mentioned patent application is hereby incorporated by reference herein and made a part of this specification.

### TECHNICAL FIELD

The disclosure relates to a control device including a connector that connects a circuit board in a case with an external device.

### BACKGROUND

As a control device for controlling devices such as motors, there is a control device in which a connector for electrically connecting a circuit board with an external device is attached to a case that accommodates the circuit board (for example, see Patent Document 1 (Japanese Patent Application Laid-Open No. 2001-237557)).

The control device described in Patent Document 1 is provided with an opening for attaching the connector to the case of the control device. The circuit board is accommodated inside the case, and the connector is attached to the opening of the case. Resin is filled inside the case in this state. Since the periphery of the circuit board in this control device is covered by the resin filled in the case, high waterproof and dustproof properties are maintained in the case.

However, in the case of this control device, resin is filled in the entire area inside the case that accommodates the circuit board, so the resin amount used is large. Therefore, in this control device, the large amount of filled resin leads to an increase in product weight and also tends to cause a rise in product cost.

As a countermeasure, a control device has been devised in which a liquid-tight adhesive is filled only between a connector holding portion of the case and the connector (for example, see Patent Document 2 (Japanese Patent No. 4729525)).

In the control device described in Patent Document 2, the case that accommodates the circuit board is formed by a first case and a second case. The first case and the second case have end surfaces abutting against each other, and are coupled by bolt fastening or the like in that state. A holding opening for holding the connector is formed in a part of the abutting portions of the first case and the second case. The connector is held in the holding opening during assembly of the first case and the second case. After the first case and the second case are coupled, the liquid-tight adhesive is filled in the gap between the connector and the holding opening.

The control device formed in this way prevents the intrusion of liquid and dust from the gap between the connector and the case by the hardened adhesive.

Generally, components have tolerances, and distortion may occur during molding of components. Therefore, even in the case of the control device described in Patent Document 2, variations occur in the gap between the holding opening and the connector due to tolerances and distortion during molding. In the case where variations in this gap are large, there is a concern that the adhesive may flow into the case from the portion where the gap is large. If a large amount of adhesive flows into the case through a part of the gap, it becomes difficult to stably seal around the connector with the adhesive.

Thus, the disclosure provides a control device that is capable of suppressing unnecessary adhesive from flowing into the case, and stably sealing around the connector.

### SUMMARY

A control device according to one aspect of the disclosure adopts the following configuration.

That is, a control device according to one aspect of the disclosure includes a circuit board; a connector electrically connected to the circuit board; a first case and a second case coupled to each other to accommodate the circuit board inside, and having a holding opening formed in a part of mutually abutting portions for holding the connector; and an adhesive being liquid-tight and filled between the holding opening and an outer peripheral surface of the connector, in which a case-side concave-convex engagement portion is provided annularly on a contact portion of the holding opening with the outer peripheral surface of the connector, and a connector-side concave-convex engagement portion to be engaged with the case-side concave-convex engagement portion is provided annularly on a contact portion of the outer peripheral surface of the connector with the holding opening.

With the above configuration, the connector-side concave-convex engagement portion on the outer periphery of the connector is engaged with the case-side concave-convex engagement portion of the case (first case and second case). In the case where the liquid-tight adhesive is filled between the holding opening on the case side and the outer peripheral surface of the connector from the outside of the case in this state, the adhesive enters a part toward the outside of the case in the gap between the case-side concave-convex engagement portion and the connector-side concave-convex engagement portion. At this time, the case-side concave-convex engagement portion and the connector-side concave-convex engagement portion form a labyrinth-like contact portion from the outside to the inside of the case, and the labyrinth-like contact portion is arranged annularly so as to surround the peripheral area of the connector. Therefore, entry of the adhesive from a part of the peripheral area of the connector into the case is restricted by the labyrinth-like contact portion.

An annular recess portion that forms an adhesive filling portion between the recess portion and the connector may be connected to an edge portion of the holding opening toward a case outer side, and the adhesive may be filled in the adhesive filling portion.

In this case, when the adhesive is filled in the adhesive filling portion, the outer peripheral surface of the connector is stably fixed to the case (first case and second case) by the filled adhesive, and the space between the outer peripheral surface of the connector and the case is sealed more liquid-tightly.

It is desirable that the abutting portions of the first case and the second case facing the recess portion have bent contact surfaces that are bent along a thickness direction and an abutting direction of the first case and the second case.

In this case, at the abutting portions of the first case and the second case that are arranged facing the recess portion without being engaged with the connector in a concave-convex manner, the bent contact surfaces constitute a labyrinth-like contact portion. Therefore, at the abutting portions of the first case and the second case that are arranged facing the recess portion, the flow of the adhesive from the recess portion into the case is suppressed by the bent contact surfaces.

It is more desirable that the bent contact surfaces are bent in multiple stages.

In this case, the bent contact surfaces bent in multiple stages make it possible to more reliably restrict entry of the adhesive from the recess portion into the case.

The connector may include a bottomed cylindrical connector body and a flange portion that projects outward from an outer peripheral surface of the connector body, in which at least a part of the connector-side concave-convex engagement portion is formed on the flange portion.

In this case, at least a part of the connector-side concave-convex engagement portion is formed on the flange portion that projects outward from the connector body. Therefore, by appropriately adjusting the shape and size of the flange portion, the connector can be formed into a shape that is easy to assemble to the first case or the second case.

The connector-side concave-convex engagement portion may be constituted by a groove, and the case-side concave-convex engagement portion may be constituted by a ridge.

In this case, the ridge does not protrude from the outer side of the flange portion of the connector, so it becomes possible to downsize the connector, and the connector becomes less likely to be damaged during transport or assembly of the connector.

The connector may be coupled to the circuit board inside the first case and the second case.

In this case, the connector that is firmly fixed to the first case and the second case by the liquid-tight adhesive is connected to the circuit board inside the case (first case and second case), so it becomes possible to efficiently suppress vibration of the circuit board.

In the above-described control device, concave-convex engagement portions that are mutually engaged are formed annularly at the respective contact portions of the holding opening on the case side and the outer peripheral surface of the connector, making it possible to suppress unnecessary adhesive from flowing into the case with these concave-convex engagement portions. Therefore, in the case of adopting the above-described control device, the periphery of the connector can be stably sealed.

### BRIEF DESCRIPTION OF THE DRAWINGS

FIG. 1 is a perspective view of the control device according to an embodiment.

FIG. 2 is a view taken along arrow II in FIG. 1.

FIG. 3 is a perspective view of the control device according to an embodiment with some components removed.

FIG. 4 is a perspective view of the control device according to an embodiment with some more components removed.

FIG. 5 is a perspective view of the connector according to an embodiment.

FIG. 6 is a cross-sectional view taken along line VI-VI in FIG. 2.

FIG. 7 is a cross-sectional view taken along line VII-VII in FIG. 2.

FIG. 8 is a cross-sectional view taken along line VIII-VIII in FIG. 2.

FIG. 9 is a cross-sectional view taken along line IX-IX in FIG. 2.

### DESCRIPTION OF THE EMBODIMENTS

Hereinafter, an embodiment of the disclosure will be described based on the drawings.

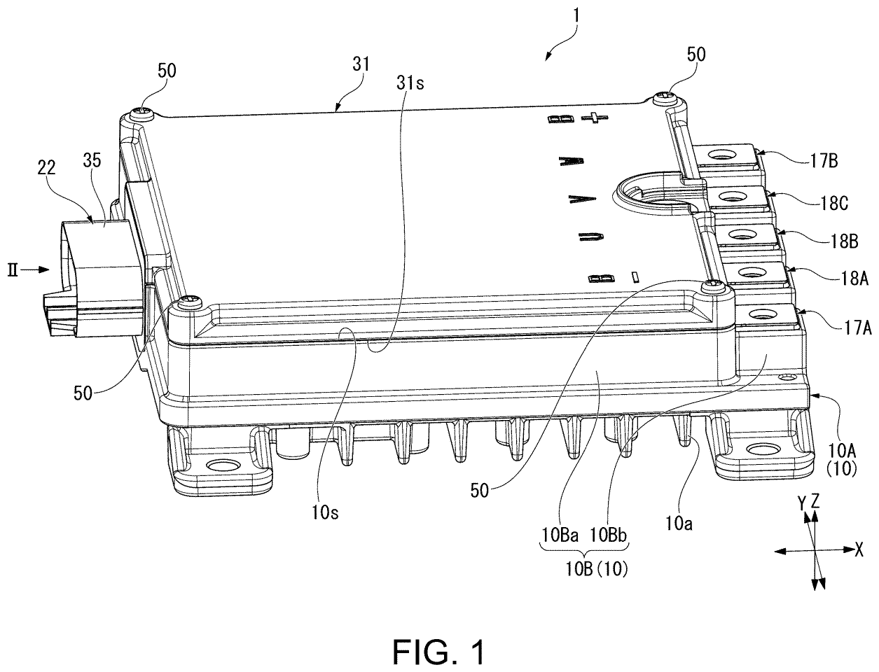

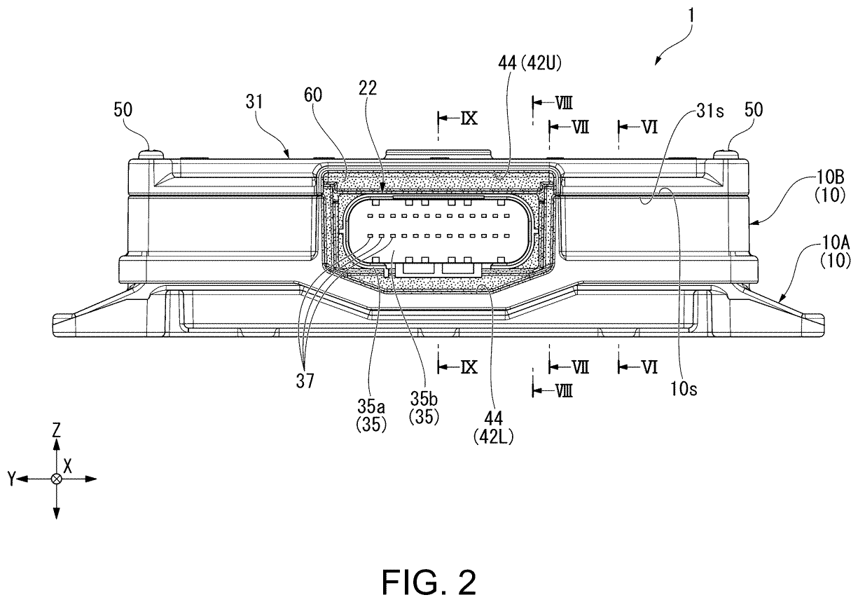

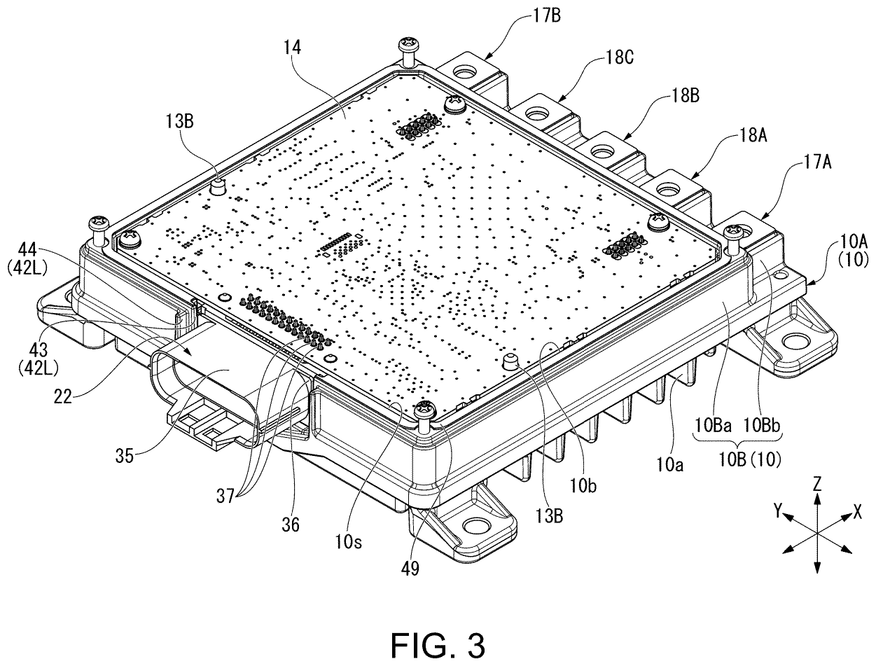

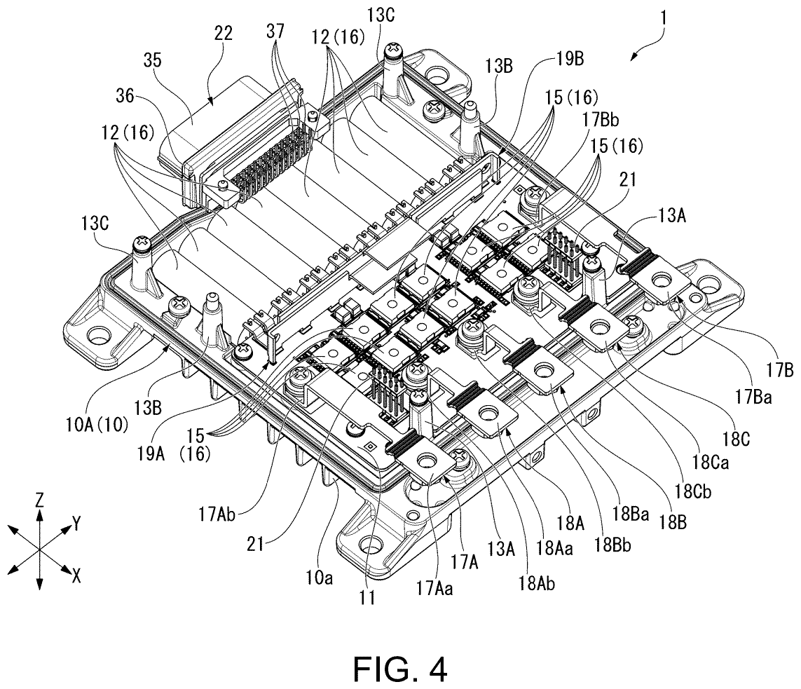

FIG. 1 is a perspective view of a control device 1 of this embodiment, and FIG. 2 is a view taken along arrow II in FIG. 1. FIG. 3 is an exploded perspective view of the control device 1 with some components removed, and FIG. 4 is a perspective view of the control device 1 with more components removed.

The control device 1 has an inverter function that converts DC power supplied from a battery (not shown) into AC power, and drives a motor (AC motor) (not shown) with the converted AC power. The control device 1 includes a thin rectangular parallelepiped first case 10 having one surface opened, and a second case 31 coupled to the first case 10 so as to close an opening 10b of the first case 10. Multiple fins 10a for heat dissipation are disposed to protrude from the outer surface of the first case 10. The second case 31 is detachably attached to the first case 10 by multiple screws 50.

Hereinafter, for convenience of description, the side of the first case 10 where the opening 10b is located is referred to as “upper,” and the opposite side is referred to as “lower.”

### <Overall Configuration of Control Device>

The first case 10 includes a base member 10A made of an aluminum alloy (metal) and formed by aluminum die casting or the like, and a case body 10B made of resin and fixed to the upper portion of the base member 10A. The base member 10A is formed in a substantially rectangular shape in top view. On the upper surface side of the base member 10A, a first board 11, multiple capacitors 12, etc. (see FIG. 4) which will be described in detail later are attached. On the lower surface side of the base member 10A, multiple fins 10a for heat dissipation are formed.

The case body 10B includes a body block portion 10Ba having a rectangular frame shape in top view, and a bus bar support portion 10Bb connected to one side surface of the body block portion 10Ba. The body block portion 10Ba has the above-mentioned opening 10b that opens toward the upper side. The periphery of the first board 11 and the multiple capacitors 12 attached to the upper surface side of the base member 10A is surrounded by the peripheral wall of the body block portion 10Ba. One end portion of each of multiple bus bars (battery-side bus bars 17A and 17B, and motor-side bus bars 18A, 18B, and 18C) is supported by the bus bar support portion 10Bb.

FIG. 3 shows a state in which the second case 31 is removed. Further, FIG. 4 shows a state in which the case body 10B and the second case 31 are removed together with a second board 14 which will be described later.

As shown in FIG. 4, multiple support column portions 13A, 13B, and 13C that protrude toward the upper side are provided on the upper surface of the base member 10A. The second board 14 is supported on the upper portions of the multiple support column portions 13A, 13B, and 13C, as shown in FIG. 3. The second board 14 is arranged on the upper side of the first board 11 and the multiple capacitors 12 to be substantially parallel to the first board 11. As shown in FIG. 4, the first board 11 is arranged toward one side of the upper surface of the base member 10A having a substantially rectangular shape in top view, and the multiple capacitors 12 are arranged toward the other side of the upper surface of the base member 10A.

The first board 11 is a printed circuit board (PWB) on which multiple electronic components including a switching element 15 are mounted. Multiple switching elements 15 are combined together with the capacitors 12 to constitute the main part of a power control circuit 16. The power control circuit 16 performs ON/OFF operations based on control of the switching elements 15 performed by a controller (not shown), thereby converting DC power of the battery into three-phase AC power.

A pair of battery-side bus bars 17A and 17B that are electrodes for energization on the battery side, and three motor-side bus bars 18A, 18B, and 18C that are electrodes for energization on the motor side are connected to the power control circuit 16. The pair of battery-side bus bars 17A and 17B are connectable to the positive pole and negative pole of the battery via connection cables (not shown), respectively. The three motor-side bus bars 18A, 18B, and 18C are connectable to U-phase, V-phase, and W-phase power supply portions of the motor via connection cables (not shown), respectively.

As shown in FIG. 4, the capacitors 12 arranged toward the other side of the base member 10A are each formed in a substantially cylindrical shape. These multiple capacitors 12 are arranged in parallel in a direction orthogonal to the longitudinal direction (axial direction). The multiple capacitors 12 are connected to the circuit on the first board 11 via bus bars 19A and 19B for connection that are surface-mounted on the first board 11. The capacitors 12 are constituted by, for example, aluminum electrolytic capacitors or the like.

Hereinafter, the direction along the longitudinal direction (axial direction) of the capacitors 12 is referred to as the X direction. Further, the direction in which the capacitors 12 are arranged in parallel is referred to as the Y direction, and the direction orthogonal to the X direction and the Y direction is referred to as the Z direction. Arrows respectively indicating the X direction, the Y direction, and the Z direction are marked at appropriate positions in the drawings.

A positive-side circuit terminal and a negative-side circuit terminal (not shown) that are power input portions from the battery are mounted on the upper surface of the first board 11. These circuit terminals are arranged in the vicinity of the end portions on both sides in the Y direction of the first board 11. The battery-side bus bars 17A and 17B that are electrodes for energization are respectively connected to the positive-side circuit terminal and the negative-side circuit terminal on the first board 11.

The battery-side bus bars 17A and 17B are both formed by long plate-shaped conductive metal plates. One end side in the longitudinal direction of each of the battery-side bus bars 17A and 17B serves as a terminal fixing portion 17Aa, 17Ba that is attached to the upper surface of one end side in the X direction of the first case 10, and the other end side in the longitudinal direction serves as a circuit fixing portion 17Ab, 17Bb that is connected to the above-mentioned positive-side circuit terminal and negative-side circuit terminal on the first board 11. The battery-side bus bars 17A and 17B are respectively fixed to the bus bar support portion 10Bb and the first board 11 by the terminal fixing portions 17Aa and 17Ba and the circuit fixing portions 17Ab and 17Bb, with the longitudinal direction along the X direction. In addition, a part of each of the battery-side bus bars 17A and 17B penetrates through the peripheral wall of the body block portion 10Ba and is embedded in the peripheral wall.

Furthermore, three output-side circuit terminals for U-phase, V-phase, and W-phase (not shown) that are power output portions to the motor are mounted on the upper surface of the first board 11. These output-side circuit terminals are arranged with substantially equal spacing in the Y direction in the central region in the Y direction of the first board 11. The motor-side bus bars 18A, 18B, and 18C that are electrodes for energization are respectively connected to these output-side circuit terminals.

The motor-side bus bars 18A, 18B, and 18C are formed by long plate-shaped conductive metal plates, similar to the battery-side bus bars 17A and 17B. One end side in the longitudinal direction of each of the motor-side bus bars 18A, 18B, and 18C serves as a terminal fixing portion 18Aa, 18Ba, 18Ca that is attached to the upper surface of one end side in the X direction of the first case 10, and the other end side in the longitudinal direction serves as a circuit fixing portion 18Ab, 18Bb, 18Cb that is connected to the above-mentioned output-side circuit terminals on the first board 11. The motor-side bus bars 18A, 18B, and 18C are respectively fixed to the bus bar support portion 10Bb and the first board 11 by the terminal fixing portions 18Aa, 18Ba, and 18Ca and the circuit fixing portions 18Ab, 18Bb, and 18Cb, with the longitudinal direction along the X direction. A part of each of the motor-side bus bars 18A, 18B, and 18C penetrates through the peripheral wall of the body block portion 10Ba and is embedded in the peripheral wall, similar to the terminal fixing portions 17Aa and 17Ba.

The second board 14 is a printed circuit board (PWB) on which electronic components are mounted. The circuit printed on the second board 14 is connected to the circuit on the first board 11 via an inter-board connector 21 (see FIG. 4). Further, a connector 22 for signal input/output is coupled to the other end in the X direction of the second board 14. The connector 22 is sandwiched from the up-down direction by the first case 10 and the second case 31, and is held by the first case 10 and the second case 31 in that state. Multiple signal terminals protruding from the connector 22 are connected to the circuit on the second board 14.

In this embodiment, the second board 14 constitutes a circuit board that is accommodated inside the first case 10 and the second case 31. The holding structure of the connector 22 formed by the first case 10 and the second case 31 will be described below.

### <Holding Structure of Connector>

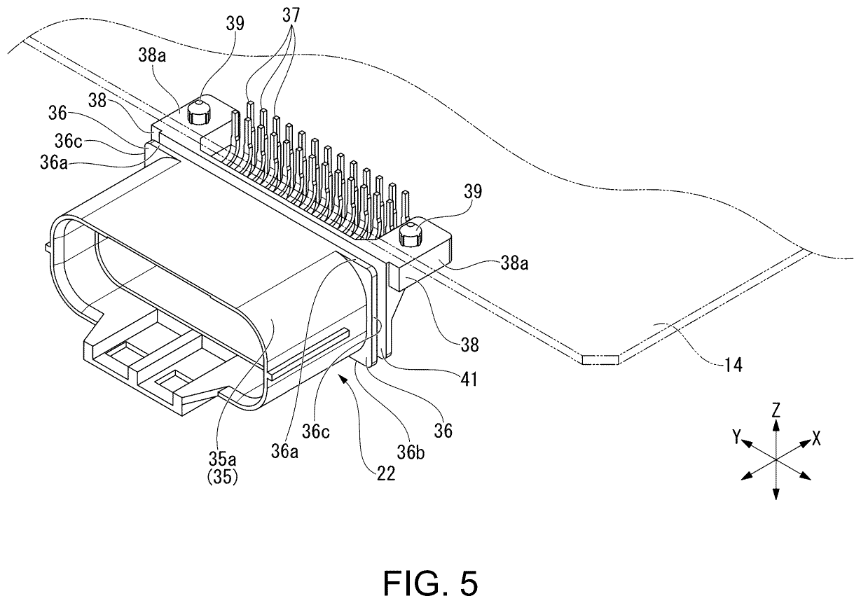

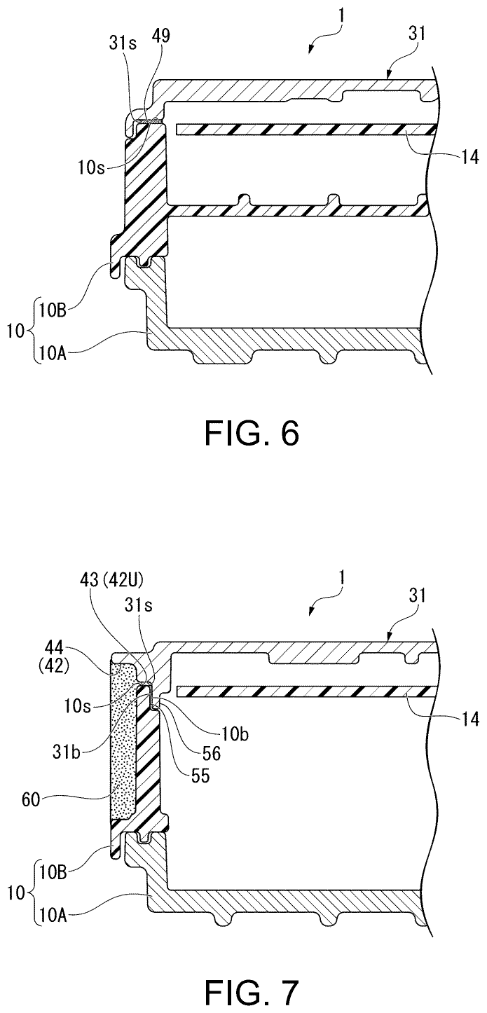

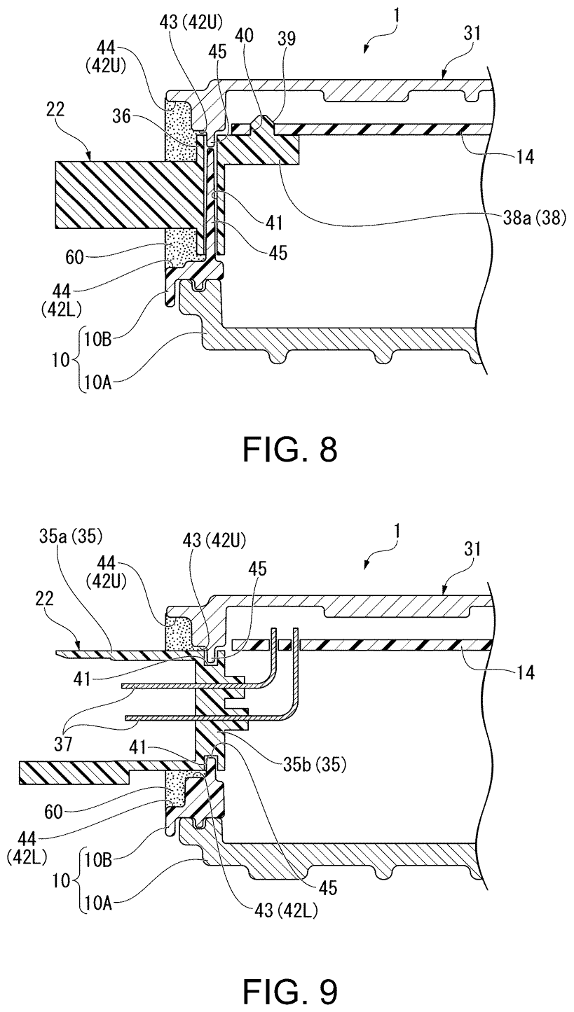

FIG. 5 is a perspective view of the connector 22. FIG. 6 is a cross-sectional view taken along line VI-VI in FIG. 2, and FIG. 7 is a cross-sectional view taken along line VII-VII in FIG. 2. In addition, FIG. 8 is a cross-sectional view taken along line VIII-VIII in FIG. 2, and FIG. 9 is a cross-sectional view taken along line IX-IX in FIG. 2.

The connector 22 includes a bottomed cylindrical connector body 35, and a pair of flange portions 36 that project outward from the outer surface on one end side in the longitudinal direction of the connector body 35. The connector body 35 has a cylindrical peripheral wall 35a having an elongated hole shape in front view, and a bottom wall 35b (see FIG. 9) that closes one end portion in the longitudinal direction of the peripheral wall 35a.

Hereinafter, for convenience of description, regarding the connector 22, the side where the peripheral wall 35a opens is referred to as “front,” and the side where the bottom wall 35b is arranged is referred to as “rear.” Also, in regard to the first case 10 and the second case 31, these may be collectively referred to as “cases 10 and 31.”

As shown in FIG. 9, the connector 22 is held by the cases 10 and 31 so that the bottom wall 35b (wall on the rear portion side) of the connector body 35 faces the inside of the cases 10 and 31. Multiple signal pins 37 are fixed to the bottom wall 35b of the connector body 35 by penetrating in the plate thickness direction. Each of the multiple signal pins 37 has one end side protruding inside the peripheral wall 35a of the connector body 35 so as to extend along the longitudinal direction of the peripheral wall 35a. The other end sides of the multiple signal pins 37 are bent toward the upper side and connected to the circuit on the second board 14 (circuit board).

In addition, substantially L-shaped connection brackets 38 are integrally formed at two positions spaced apart in the Y direction at the rear portion of the bottom wall 35b of the connector body 35. Each connection bracket 38 has an upper side 38a that extends from the upper portion of the bottom wall 35b toward the rear side. A protrusion 39 for connection is provided to protrude from the upper surface of the upper side 38a of each connection bracket 38. Each protrusion 39 is fitted into a corresponding connection hole 40 (see FIG. 8) at the edge of the second board 14. The connector 22 is thereby coupled to the edge of the second board 14.

The pair of flange portions 36 extend from the outer surface of the rear portion of the connector body 35 toward one side and the other side in the Y direction, respectively. The left and right flange portions 36 are formed in a horizontally elongated rectangular shape in front view when combined with the connector body 35. In other words, the pair of flange portions 36 have a flat upper side 36a that linearly continues to the flat upper surface of the connector body 35, and a flat lower side 36b that linearly continues to the flat lower surface of the connector body 35. Also, the left and right flange portions 36 have flat lateral sides 36c that connect the respective extending ends of the upper side 36a and the lower side 36b. On the upper and lower surfaces of the rear portion side of the connector body 35 and the outer surfaces of the left and right flange portions 36 (surfaces facing outward of the upper side 36a, the lateral sides 36c, and the lower side 36b), a groove 41 of a predetermined depth is formed continuously in an annular shape.

In this embodiment, the groove 41 constitutes the connector-side concave-convex engagement portion.

As shown in FIG. 1 and FIG. 2, an upper end surface 10s of the peripheral wall of the first case 10 and a lower end surface 31s of the peripheral wall of the second case 31 abut against each other. In this embodiment, the upper end surface 10s of the peripheral wall of the first case 10 and the lower end surface 31s of the peripheral wall of the second case 31 constitute the abutting portions of the first case 10 and the second case 31. Hereinafter, the upper end surface 10s of the peripheral wall of the first case 10 is referred to as “lower abutting portion 10s,” and the lower end surface 31s of the peripheral wall of the second case 31 is referred to as “upper abutting portion 31s.”

A cutout portion 42L that recesses toward the lower side and has a substantially rectangular shape in front view is formed in the wall portion on the other end side in the X direction of the peripheral wall of the first case 10. This cutout portion 42L is formed to recess downward so as to separate a part of the lower abutting portion 10s of the first case 10 in the circumferential direction. Similarly, a cutout portion 42U that recesses toward the upper side and has a substantially rectangular shape in front view is formed in the wall portion on the other side in the X direction of the peripheral wall of the second case 31. This cutout portion 42U is formed to recess upward so as to separate a part of the upper abutting portion 31s in the circumferential direction. The two cutout portions 42L and 42U are arranged to face each other in the case of the first case 10 and the second case 31 being connected.

As shown in FIG. 9, the cutout portions 42L and 42U of the first case 10 and the second case 31 face each other to form a substantially rectangular holding opening 43. The holding opening 43 is formed at a position toward the inside of the cases 10 and 31 of the cutout portions 42L and 42U. The holding opening 43 has a contact portion that comes into contact with the outer peripheral surface on the rear portion side of the connector 22 (the outer peripheral surface combining the connector body 35 and the flange portions 36). A ridge 45 that protrudes in the inward direction of the holding opening 43 is formed on the contact portion. The ridge 45 is formed continuously in an annular shape along the inner peripheral surface of the holding opening 43. The annularly formed ridge 45 is fitted into an annular recess portion 44 formed on the outer peripheral surface toward the rear portion of the connector 22.

In this embodiment, the ridge 45 constitutes the case-side concave-convex engagement portion.

In addition, the annular recess portion 44 that is adjacent to the holding opening 43 and has a larger opening area than the holding opening 43 is formed within the cutout portions 42L and 42U. The recess portion 44 is formed across the two cutout portions 42L and 42U. The recess portion 44 is connected to the edge portion of the holding opening 43 toward the case outer side (toward the other end in the X direction). In the recess portion 44, a relief portion expands in a stepped manner from the edge portion toward the case outer side of the holding opening 43 in a direction away from the outer peripheral surface of the connector 22, and has an inner surface shape that is one size larger than the inner surface of the holding opening 43 as a whole. This annular recess portion 44 forms the annular adhesive filling portion between the annular recess portion 44 and the outer peripheral surface of the connector body 35 of the connector 22.

An adhesive 60 having liquid tightness is filled in the adhesive filling portion between the annular recess portion 44 and the connector body 35. The adhesive filled in the adhesive filling portion flows into a part of the gap between the holding opening 43 adjacent to the recess portion 44 and the connector body 35. Within the holding opening 43, the annular ridge 45 protruding from the holding opening 43 is engaged with the annular groove 41 on the outer periphery of the connector body 35 in a concave-convex manner. Therefore, the adhesive 60 that flows into the gap is blocked from flowing into the cases 10 and 31 by the labyrinth-like contact portion formed by the ridge 45 and the groove 41.

Furthermore, on the outer side in the left-right direction (Y direction) of the engagement portion between the holding opening 43 and the connector 22 (see FIG. 8 and FIG. 9), there exists a portion where the lower abutting portion 10s and the upper abutting portion 31s abut in the up-down direction at a position facing the recess portion 44 (see FIG. 7). As shown in FIG. 7, this portion does not have the connector 22, and the lower abutting portion 10s and the upper abutting portion 31s do not overlap with the connector 22 in the front-rear direction. Therefore, in this portion, the labyrinth-like sealing effect of the ridge 45 on the holding opening 43 side and the groove 41 on the connector 22 side cannot be obtained.

In this portion, as shown in FIG. 7, a cutout portion 55 having a rectangular shape in side view is formed on the upper rear surface side of the wall portion of the first case 10 that forms the lower abutting portion 10s. The cutout portion 55, together with the front region of the lower abutting portion 10s, forms a crank-shaped bent contact surface 10b in side view.

On the other hand, the upper abutting portion 31s is provided with a protruding lap wall 56 that engages with the cutout portion 55 from the rear side of the wall portion of the first case 10. The lap wall 56 is formed in a rectangular shape in side view, similar to the cutout portion 55. The lap wall 56, together with the front region of the upper abutting portion 31s, forms a bent contact surface 31b on the second case 31 side.

The bent contact surfaces 10b and 31b of the first case 10 and the second case 31 are bent along the thickness direction and the abutting direction of the peripheral walls of the cases 10 and 31. In this embodiment, the bent contact surfaces 10b and 31b are bent in two stages. However, the number of bent stages of the bent contact surfaces 10b and 31b may be one stage or three or more stages.

As shown in FIG. 7, in the upper abutting portion 31s and the lower abutting portion 10s that face the recess portion 44, the bent contact surfaces 31b and 10b come into contact with each other in a labyrinth shape. Therefore, even in the case where the adhesive 60 filled in the adhesive filling portion enters the gap between the upper abutting portion 31s and the lower abutting portion 10s from the recess portion 44 side, the adhesive 60 is blocked from flowing into the cases 10 and 31 by the bent contact surfaces 31b and 10b.

### <Assembly of Connector>

The connector 22 is assembled to the cases 10 and 31 that accommodate devices such as boards (first board 11, second board 14) and capacitors 12 inside as follows.

Before fastening and fixing the first case 10 and the second case 31, the groove 41 on the outer periphery of the rear portion side of the connector 22 is engaged with the ridge 45 of the holding opening 43 on the first case 10 side. At this time, the connector 22 can be slid from the upper side in a state aligned with the holding opening 43 on the first case 10 side to engage the ridge 45 with the groove 41. In this embodiment, since the flange portions 36 that project laterally in a substantially rectangular shape are extended at the rear portion of the connector 22, the connector 22 can be slid from above to below to easily engage the ridge 45 with the groove 41.

Next, the second case 31 is aligned with the first case 10, and by lowering the second case 31, the ridge 45 of the holding opening 43 on the second case 31 side is engaged with the upper region of the groove 41 on the outer periphery of the rear portion side of the connector 22. Further, the lap wall 56 of the upper abutting portion 31s positioned at a portion facing the recess portion 44 is engaged with the cutout portion 55 of the lower abutting portion 10s, as shown in FIG. 7.

A sealing material 49 is placed on the upper surface of the lower abutting portion 10s of the first case 10, and the sealing material 49 may be a liquid-tight adhesive.

Then, the four corners of the first case 10 are fastened and fixed to the second case 31 by the screws 50.

Finally, the adhesive 60 is filled into the adhesive filling portion between the recess portion 44, which is formed within the cutout portions 42L and 42U of the first case 10 and the second case 31, and the outer peripheral surface of the connector 22. At this time, a part of the adhesive 60 filled in the adhesive filling portion enters the gap between the ridge 45 on the connector 22 side and the groove 41 on the holding opening 43 side. However, the adhesive 60 entering the gap is prevented from flowing into the cases 10 and 31 by the labyrinth-like contact portion between the ridge 45 and the groove 41, as described above.

In the case where the adhesive 60 filled in the adhesive filling portion is hardened in this state, the connector 22 is fixed to the cases 10 and 31 by the hardened adhesive 60, and the space between the connector 22 and the cases 10 and 31 is sealed in a liquid-tight manner. Since the sealing material 49 is interposed between the lower abutting portion 10s of the first case 10 and the upper abutting portion 31s of the second case 31, the entire area between the first case 10 and the second case 31, including the attaching portion of the connector 22, is sealed.

### <Operation and Effect>

In the control device 1 of this embodiment, the ridge 45 that is the case-side concave-convex engagement portion is formed annularly in the holding opening 43 on the case side, and the groove 41 that is the connector-side concave-convex engagement portion is formed annularly on the outer periphery of the rear portion side of the connector 22. Then, the ridge 45 on the case side is engaged with the groove 41 on the connector side, and in this state, the liquid-tight adhesive 60 is filled between the holding opening 43 and the connector 22 from the outside of the cases 10 and 31. When filling this adhesive 60, the adhesive 60 enters a part of the gap between the ridge 45 and the groove 41 toward the outside of the cases 10 and 31. However, the ridge 45 and the groove 41 form the labyrinth-like contact portion from the outside to the inside of the cases 10 and 31, and the labyrinth-like contact portion is arranged annularly so as to surround the peripheral area of the connector 22. Therefore, in the control device 1 of this embodiment, unnecessary flow of the adhesive 60 from the peripheral area of the connector 22 into the cases 10 and 31 can be suppressed. In this embodiment, the case-side concave-convex engagement portion is constituted by the ridge 45 and the connector-side concave-convex engagement portion is constituted by the groove 41, but conversely, the case-side concave-convex engagement portion may be constituted by a groove and the connector-side concave-convex engagement portion may be constituted by a ridge.

Therefore, in the case of adopting the control device 1 of this embodiment, unnecessary adhesive 60 can be suppressed from flowing into the cases 10 and 31, and the periphery of the cases 10 and 31 can be stably sealed. Accordingly, it becomes possible to contribute to Goal 7 “Ensure access to affordable, reliable, sustainable and modern energy for all” and Goal 8 “Promote sustained, inclusive and sustainable economic growth, full and productive employment and decent work for all” of the Sustainable Development Goals (SDGs) led by the United Nations.

Moreover, the control device 1 of this embodiment has a configuration in which the annular recess portion 44 that forms the adhesive filling portion between the annular recess portion 44 and the connector 22 is connected to the edge portion of the holding opening 43 toward the case outer side, and the liquid-tight adhesive 60 is filled in the adhesive filling portion inside the recess portion 44. Therefore, in the case where the adhesive 60 is filled in the adhesive filling portion, the outer peripheral surface of the connector 22 is stably fixed to the cases 10 and 31 by the adhesive 60, and the space between the outer peripheral surface of the connector 22 and the cases 10 and 31 is sealed more liquid-tightly.

Accordingly, in the case of adopting this configuration, unnecessary flow of the adhesive 60 from the peripheral area of the connector 22 into the cases 10 and 31 can be suppressed, while sealing between the cases 10 and 31 and the connector 22 and fixing of the connector 22 can be made more reliable.

Furthermore, the control device 1 of this embodiment is provided with the bent contact surfaces 10b and 31b that are bent along the thickness direction and the abutting direction of the cases 10 and 31 on the lower abutting portion 10s and the upper abutting portion 31s which are arranged at positions facing the recess portion 44. The bent contact surfaces 10b and 31b are formed in a labyrinth shape by the lap wall 56 on the upper abutting portion 31s side and the cutout portion 55 on the lower abutting portion 10s side. Therefore, the adhesive 60 can be suppressed from flowing from the recess portion 44 into the cases 10 and 31 through the gap between the lower abutting portion 10s and the upper abutting portion 31s that are arranged facing the recess portion 44 by the bent contact surfaces 10b and 31b.

Accordingly, in the case of adopting this configuration, the adhesive 60 can be suppressed from flowing from the recess portion 44 into the cases 10 and 31 even in the portion where the connector 22 and the holding opening 43 are not engaged in a concave-convex manner.

Particularly, in the control device 1 of this embodiment, the bent contact surfaces 10b and 31b are bent in multiple stages. Therefore, the bent contact surfaces 10b and 31b that are bent in multiple stages can more reliably suppress the flow of the adhesive 60 from the recess portion 44 into the cases 10 and 31.

Furthermore, the control device 1 of this embodiment is provided with the flange portions 36 that project outward from the outer peripheral surface of the connector body 35, and a part of the groove 41 which is the connector-side concave-convex engagement portion is formed on the flange portions 36. Therefore, by appropriately adjusting the shape and size of the flange portions 36, the connector 22 can be formed into a shape that is easy to assemble to the cutout portions 42L and 42U of the cases 10 and 31. Particularly, in the case of forming the flange portions 36 into a shape that projects in a rectangular shape on both left and right sides as in this embodiment, the connector 22 can be easily slid and inserted from above into the cutout portion 42L by forming the lateral sides 36c of the flange portions 36 linearly in the up-down direction.

Accordingly, in the case of adopting this configuration, the assembly workability of the connector 22 can be improved.

Also, in this embodiment, the connector-side concave-convex engagement portion is constituted by the groove 41, and the case-side concave-convex engagement portion is constituted by the ridge 45. Therefore, in the case of adopting this configuration, the ridge does not protrude from the outer side of the flange portions 36 of the connector 22, so it becomes possible to downsize the connector 22, and the connector 22 becomes less likely to be damaged during transport or assembly of the connector 22.

Further, in the control device 1 of this embodiment, the connector 22 is coupled to the second board 14, which is a circuit board, within the cases 10 and 31. As a result, the second board 14 within the cases 10 and 31 is fixed to the connector 22 that is firmly fixed to the holding opening 43 of the cases 10 and 31 by the liquid-tight adhesive 60. Therefore, it becomes possible to efficiently suppress vibration of the second board 14.

Accordingly, in the case of adopting this configuration, even if the control device 1 is used in an environment where vibration is input from the outside such as a vehicle, it is still possible to suppress deterioration of the devices on the board due to large vibration of the second board 14 (circuit board).

Nevertheless, the disclosure is not limited to the above embodiment, and various design changes are possible within a range that does not depart from the gist of the disclosure. For example, in the above embodiment, the cutout portions 42L and 42U are provided in the wall portions of both the first case 10 and the second case 31, and the holding opening 43 is formed inside these cutout portions 42L and 42U. However, the cutout portion may be formed in only one of the first case 10 and the second case 31.

In addition, in the above embodiment, the flange portions 36 are formed to project on both left and right sides at the rear portion of the connector body 35, but the flange portions 36 may project annularly outward from around the rear portion of the connector body 35. It should be noted that the flange portions 36 are not necessarily provided.

Furthermore, in the above embodiment, the structure is made so that one ridge 45 on the holding opening 43 side of the cases 10 and 31 and one groove 41 on the outer peripheral surface side of the connector 22 are engaged in a concave-convex manner. However, the shape of the concave-convex engagement portions is not limited thereto. For example, two or more ridges may be provided on one side of the holding opening 43 and the outer peripheral surface of the connector 22, and corresponding two or more grooves may be provided on the other side to engage with these ridges.

Additionally, in the above embodiment, the connector 22 is mechanically coupled to the second board 14 (circuit board), but the connector 22 is not necessarily mechanically coupled to the second board 14 (circuit board).

What is claimed is:

1. A control device, comprising:
a circuit board;
a connector electrically connected to the circuit board;
a first case and a second case coupled to each other to accommodate the circuit board inside, and having a holding opening formed in a part of mutually abutting portions for holding the connector; and
an adhesive being liquid-tight and filled between the holding opening and an outer peripheral surface of the connector,
wherein a case-side concave-convex engagement portion is provided annularly on a contact portion of the holding opening with the outer peripheral surface of the connector, and
a connector-side concave-convex engagement portion to be engaged with the case-side concave-convex engagement portion is provided annularly on a contact portion of the outer peripheral surface of the connector with the holding opening.

2. The control device according to claim 1, wherein a recess portion that is annular and forms an adhesive filling portion between the recess portion and the connector is connected to an edge portion of the holding opening toward a case outer side, and
the adhesive is filled in the adhesive filling portion.

3. The control device according to claim 2, wherein the abutting portions of the first case and the second case facing the recess portion have bent contact surfaces that are bent along a thickness direction and an abutting direction of the first case and the second case.

4. The control device according to claim 3, wherein the bent contact surfaces are bent in multiple stages.

5. The control device according to claim 1, wherein the connector comprises:
a connector body being bottomed and cylindrical; and
a flange portion projecting outward from an outer peripheral surface of the connector body,
wherein at least a part of the connector-side concave-convex engagement portion is formed on the flange portion.

6. The control device according to claim 5, wherein the connector-side concave-convex engagement portion is constituted by a groove, and the case-side concave-convex engagement portion is constituted by a ridge.

7. The control device according to claim 1, wherein the connector is coupled to the circuit board inside the first case and the second case.
